(19) United States
(12) Patent Application Publication
(10) Pub. No.: US 2025/0323104 A1
(43) Pub. Date: Oct. 16, 2025

(54) TEST METHODOLOGY FOR ANALOG PHYSICAL LAYER MODULE IN SEMICONDUCTOR DIE

(71) Applicant: TAIWAN SEMICONDUCTOR MANUFACTURING COMPANY LTD., HSINCHU (TW)

(72) Inventors: YU-JIE HUANG, KAOHSIUNG CITY (TW); MU-SHAN LIN, HSINCHU CITY (TW); CHIEN-CHUN TSAI, HSINCHU COUNTY (TW)

(21) Appl. No.: 18/633,452

(22) Filed: Apr. 11, 2024

(51) Int. Cl. H01L 21/66; G01R 31/28; H01L 23/00; H01L 23/50

(52) U.S. Cl. CPC H01L 22/32; G01R 31/2889; H01L 23/50; H01L 24/16; H01L 2224/16146; H01L 2224/16225

(57) ABSTRACT

The present disclosure provides a method, which includes the following steps: dividing a plurality of first data bumps and a plurality of second data bumps within an analog physical layer module of a semiconductor die into a plurality of first segments and a plurality of second segments, respectively; sequentially activating and testing one or more subsets within the analog physical layer module simultaneously to obtain a respective subset test result of each subset, wherein each subset comprises one of the first segments and one of the second segments; and merging the respective subset test result of each subset to obtain an overall test result of the analog physical layer module.

### BACKGROUND

The chiplet system-on-chip (SOC) represents the most recent advancement in chip design methodologies within a post-Moore's law era. By employing multiple smaller chiplets, chiplet techniques effectively enhance computing performance while simultaneously reducing manufacturing costs.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIGS. 1A-1C are cross sections of different semiconductor packages in accordance with some embodiments of the present disclosure.

FIG. 2 is a plan view of an aPHY module in accordance with some embodiments of the present disclosure.

FIG. 3A is a plan view of an aPHY module in accordance with some embodiments of the present disclosure.

FIG. 3B is a plan view of the aPHY module with segments in FIG. 3A.

FIG. 4A is a diagram illustrating performing a KGD test on the first die using external test equipment in accordance with some embodiments of the present disclosure.

FIG. 4B is a diagram illustrating the aPHY module during the KGD test in FIG. 4A.

FIG. 4C is a flowchart of a method for performing the KGD test of the first die in accordance with the embodiment of FIG. 4A.

FIG. 4D is a simplified diagram of the aPHY module with the control circuit in accordance with some embodiments of the present disclosure.

FIG. 4E is a schematic diagram of the control circuit in FIG. 4D.

FIG. 4F is a schematic diagram of a clock gating component in FIG. 4D.

FIG. 5A is another diagram illustrating the aPHY module during the KGD test in FIG. 4A.

FIG. 5B is yet another diagram illustrating the aPHY module during the KGD test in FIG. 4A.

FIG. 6 is a flowchart of a method for testing an analog physical layer module within a semiconductor die in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

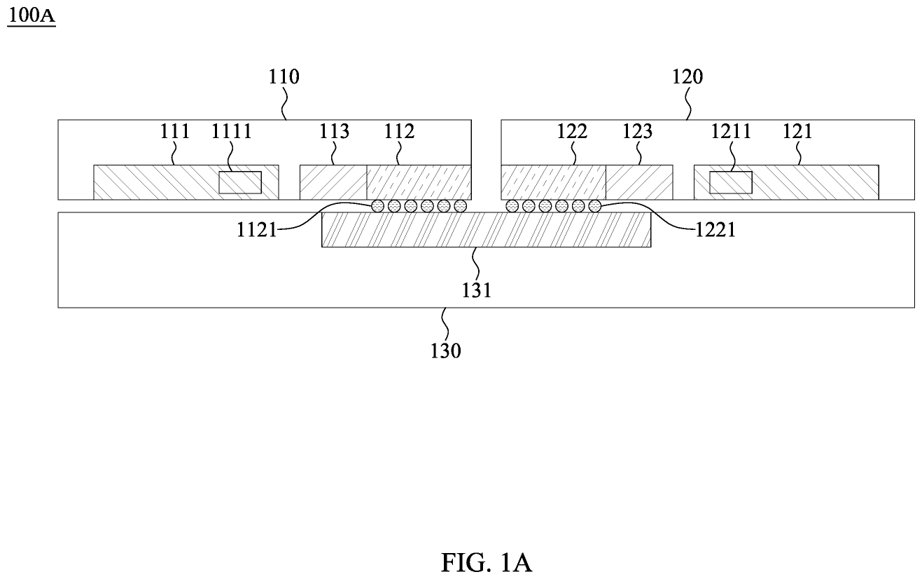

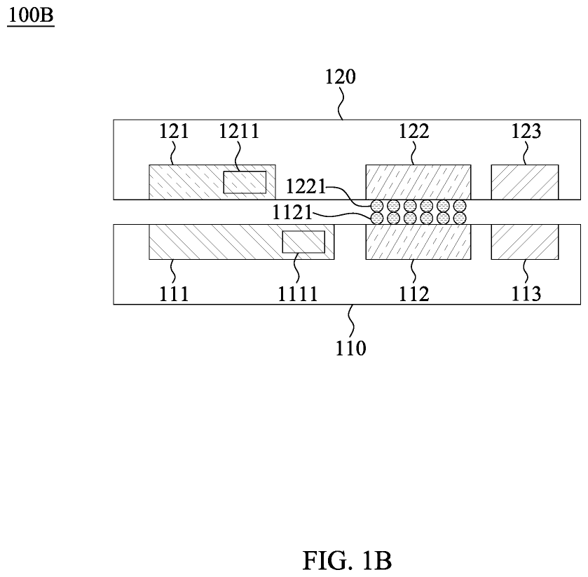

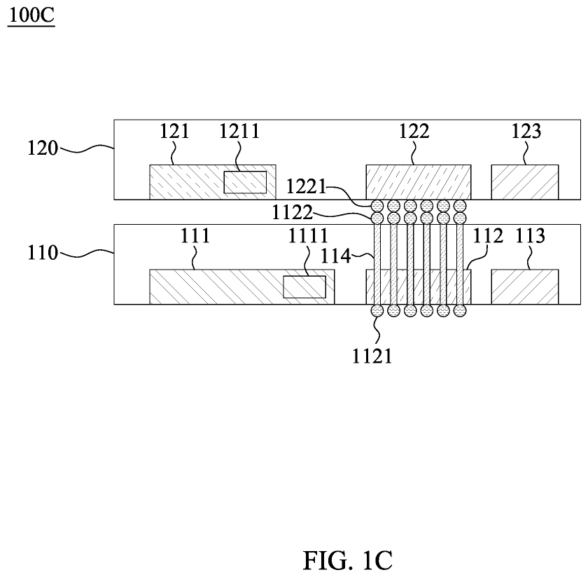

FIGS. 1A-1C are cross sections of different semiconductor packages in accordance with some embodiments of the present disclosure.

Referring to FIG. 1A, in some embodiments, the semiconductor package 100A may be any type of integrated circuit package. In the particular configuration shown in FIG. 1A, the semiconductor package 100A may be a 2.5 dimensional (2.5D) package including multiple chiplets or dies, such as a first die 110 and a second die 120. The first die 110 and the second die 120 may be electrically connected through interconnects 131 disposed or formed on a package substrate 130. In some embodiments, the interconnects 131 may be die-to-die interconnects implemented using an electronic interposer, a silicon bridge, etc., but the present disclosure is not limited thereto. Additionally, the interconnects 131 may support the UCIe (Universal Chiplet Interconnect Express) 1.1 Specification (2023), as well as earlier versions, later versions, and variations.

In some embodiments, as depicted in FIG. 1A, first die 110 may include logic circuitry 111, an analog physical layer (aPHY) module 112, and a built-in self-test (BIST) circuit 113 that are electrically connected through conductive wires or a redistribution layer (not explicitly shown) formed on first die 110. The logic circuitry 111 may be or include a central processing unit (CPU), a graphics processing unit (GPU), a data processing unit (DPU), a neural processing unit (NPU), etc., but the present disclosure is not limited thereto. The aPHY module 112 may be an UCIe physical interface for an advanced package option that includes a plurality of microbumps (μbump) 1121 configured to electrically connect to second die 120 through interconnects 131. The BIST circuit 123 may be configured to provide self-test functions to test the functionality of first die 110. It should be noted that the control circuit 1111 disposed in the logic circuitry 111 in FIG. 1A is for descriptive purposes, and it may include control gates, correction circuits, clock buffers, and clock paths disposed within the aPHY module 112.

Similarly, second die 120 may include logic circuitry 121, an analog physical layer (aPHY) module 122, and a built-in self-test (BIST) circuit 123. The logic circuitry 121 may be or include a central processing unit (CPU), a graphics processing unit (GPU), a data processing unit (DPU), a neural processing unit (NPU), a high-bandwidth memory (HBM) etc., but the present disclosure is not limited thereto. The aPHY module 122 may be an UCIe physical interface that include a plurality of microbumps (μbump) 1221 configured to electrically connect to first die 110 through interconnects 131. The microbumps 1121 of first die 110 correspond to the microbumps 1211 of second die 120. The BIST circuit 123 may be configured to provide self-test functions to test the functionality of second die 120. Additionally, logic circuitry 111 and 121 may include control circuits 1111 and 1211 configured to control segment-based known good die (KGD) test of the aPHY modules 112 and 122, respectively. It should be noted that the control circuit 1211 disposed in the logic circuitry 121 in FIG. 1A is for descriptive purposes, and it may include control gates, correction circuits, clock buffers, and clock paths disposed within the aPHY module 122.

Referring to FIG. 1B, in some embodiments, the semiconductor package 100B shown in FIG. 1B is different from the semiconductor package 100A shown in FIG. 1A, with the difference being that the semiconductor package 100B may be a three-dimensional (3D) package including multiple chiplets or dies, such as the first die 110 and the second die 120.

In some embodiments, as depicted in FIG. 1B, the logic circuitry 111 may be or include a central processing unit (CPU), a graphics processing unit (GPU), a data processing unit (DPU), a neural processing unit (NPU), etc., but the present disclosure is not limited thereto. It should be noted that the microbumps 1121 of first die 110 correspond to the microbumps 1211 of second die 120, allowing the aPHY module 122 of second die 120 being electrically connected to the aPHY module 111 of first die 110 through microbumps 1221 and 1121 using a flip chip technique (e.g., front side down). The logic circuitry 121 may be or include a central processing unit (CPU), a graphics processing unit (GPU), a data processing unit (DPU), a neural processing unit (NPU), a high-bandwidth memory (HBM) etc., but the present disclosure is not limited thereto. The 3D structure of semiconductor package 100B may reduce lengths of conductive paths between logic circuitry 111 and 121, improving the efficiency of data transmission.

Referring to FIG. 1C, in some embodiments, the semiconductor package 100C shown in FIG. 1C is different from the semiconductor package 100B shown in FIG. 1B, with the difference being that the semiconductor package 100B may be another three-dimensional (3D) package including multiple chiplets or dies, such as the first die 110 and the second die 120, using through silicon vias (TSVs) 120. Specifically, first die 110 may include TSVs 114 that can penetrate first die 110 to electrically connect microbumps 1121 of the aPHY module 112 to microbumps 1122. Additionally, the aPHY module 112 of first die 110 may be electrically connected to the aPHY module 122 of second die 120 through microbumps 1122 and 1221.

It should be noted that although one aPHY module 112 and one aPHY module 122 are disposed respectively in the first die 110 and second die 120 in the semiconductor packages 100A to 100C shown in FIGS. 1A to IC, the first die 110 and second die 120 can include more aPHY modules 112 and 122, respectively, depending on the practical circuit design of the first die 110 and second die 120.

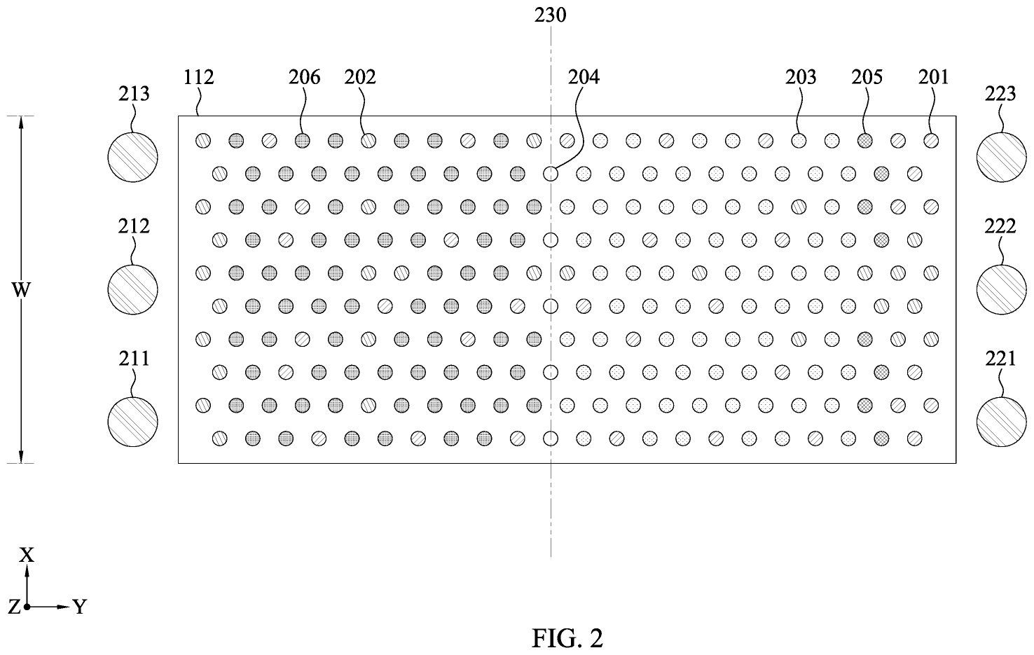

FIG. 2 is a plan view of an aPHY module in accordance with some embodiments of the present disclosure.

In some embodiments, the width W of the aPHY module 112, as depicted in FIG. 2, is 388.8 μm according to the UCIe specification 1.0. The aPHY module 112 shown in FIG. 2 may include plurality of microbumps 201 to 206 of different types and patterns. The microbumps of the same pattern belongs to one of the six types of microbumps 201 to 206. For example, microbumps 201 may refer to reference voltage microbumps (e.g., vss), while microbumps 202 may refer to input/output (I/O) power supply voltage microbumps (e.g., vccio). Microbumps 203 may include microbumps for receiver data (rxdata), RX clock signals, and RX I/O signals, while microbumps 206 may include microbumps for transmitter data (rxdata), TX clock signals, and TX I/O signals. The txdata microbumps 206 and rxdata microbumps 203 are positioned on the left and right sides of the aPHY module 112 relative to line 230. Microbumps 204 may be designated as forwarded power supply voltage bumps (e.g., vccfwdio), while microbumps 205 may refer to sideband microbumps of different types including sideband receiver data, receiver clock, transmitter data, transmitter clock, I/O power supply voltage, etc. These sideband microbumps 205 are utilized for lane repair in the event of mainband microbump (e.g., including microbumps 203 and 206) failure. It should be noted that the aPHY module 122 shown in FIGS. 1A to IC may have a width and arrangement of microbumps similar to those shown in FIG. 2.

In some embodiments, the aPHY module 112 can operate at a data transmission rate of 32 Gb/s with 64 data lines, providing a high data bandwidth between first die 110 and second die 120 in the semiconductor packages 100A to 100C shown in FIGS. 1A to IC. However, the width of the aPHY module 112, as defined by the UCIe specification, is fixed, and the bump pitch between microbumps 201 to 206, also defined by the UCIe specification, may be too small to be probed using probes of test equipment during the KGD test of first die 110. To address this issue, probe bumps 211 to 213 and 221 to 223 of substantially equal dimension can be placed along opposite sides (e.g., left and right sides) to test the functionality of the aPHY module 112. The probe bumps 211 to 213 and 221 to 223 may be relatively larger than microbumps 201 to 206, allowing one or more probes of test equipment to place on them during the KGD test of first die 110.

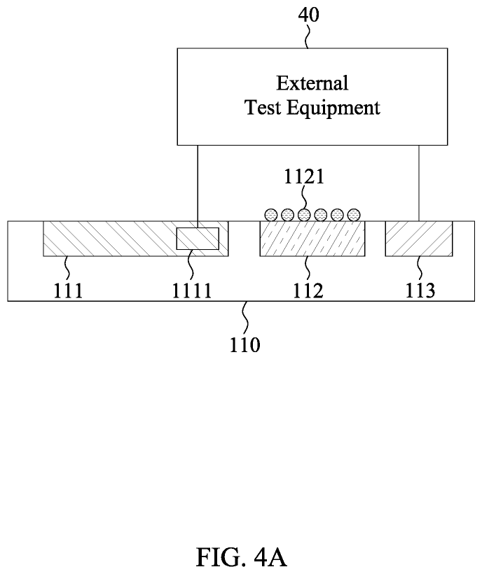

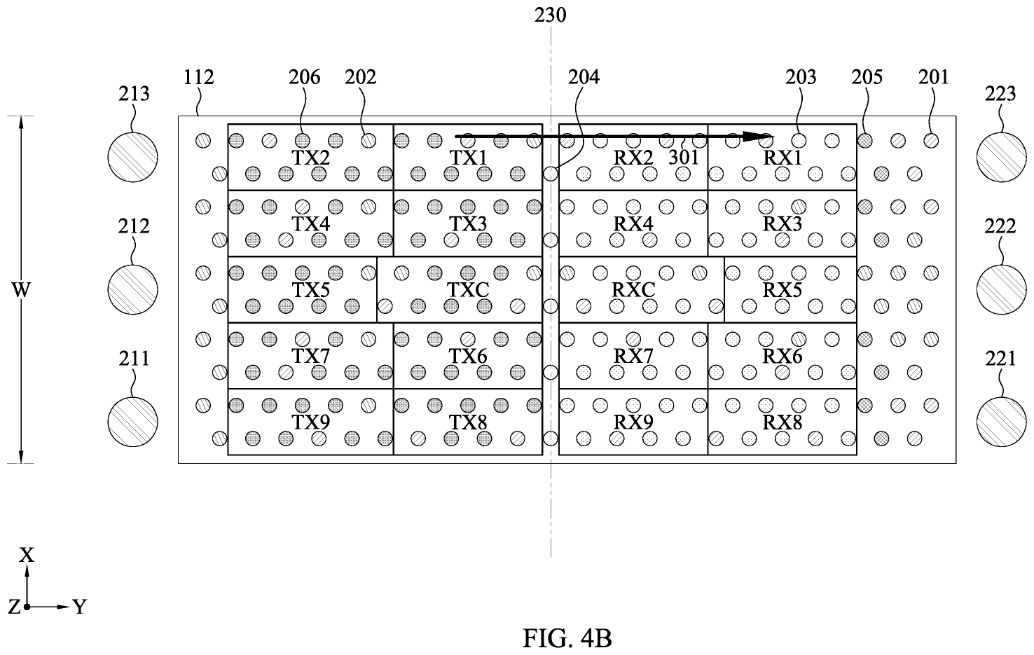

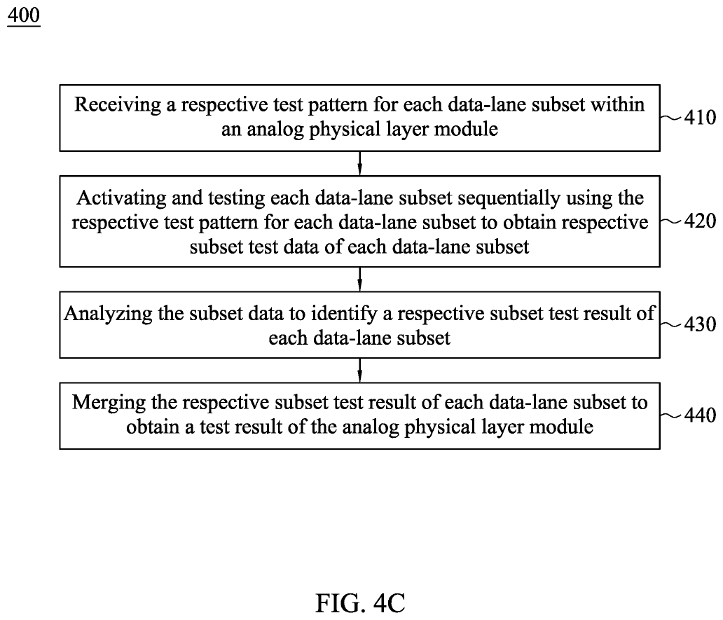

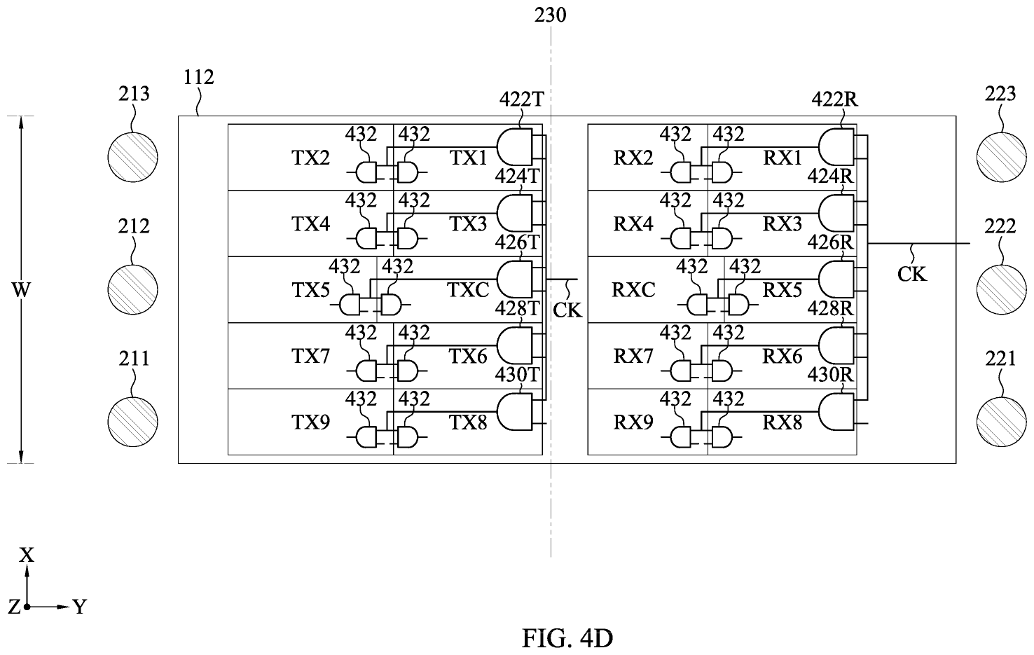

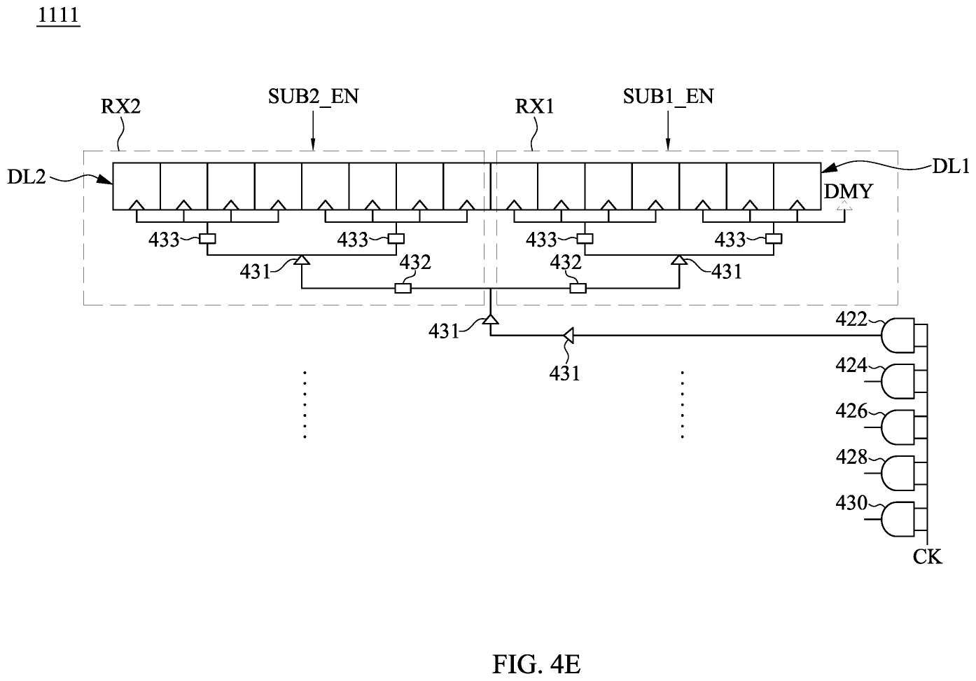

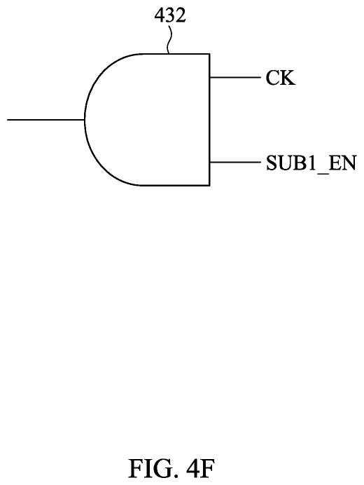

In some embodiments, the probe bumps 211, 213, and 222 server as power supply voltage probe bumps, while the probe bumps 212, 221, and 223 serve as ground voltage probe bumps. During the KGD test of first die 110, the power supply voltage is provided to the aPHY module 112 through the probe bumps 211, 213, and 222, while the ground voltage is provided to the aPHY module 112 through the probe bumps 212, 221, and 223. Specifically, the aPHY module 112 may include test circuitry (e.g., control circuit 1111 shown in FIG. 4A) disposed under the microbumps 201 to 206, allowing the txdata microbumps 206 to transmit die-to-die test signals to the corresponding rxdata microbumps 203.

In some approaches where the KGD test is performed using 64 lanes (e.g., 64 pairs of txdata and rxdata microbumps) at the data transmission rate of 32 Gb/s, the power distribution network of the aPHY module 112 extends from the probe bumps 211 to 213 and 221 to 223, which are located on the left and right sides of the aPHY module 112, to the microbumps 203 and 206 located in the center region (e.g., around line 230) of the aPHY module 112, resulting in a larger voltage (IR) drop. Additionally, these approaches involve operating all 64 lanes together during the KGD test, which can lead to a higher overall current (e.g., approximately 1.6 A) on a limited number of probe bumps 211 to 213 and 221 to 223. Specifically, three probe bumps 211 to 213 suffer from a large overall current of approximately 1.6 A, while three probe bumps 211 to 213 suffer from a large overall current of approximately 1.6 A. Accordingly, each of the three probe bumps 211 to 213 and 221 to 223 experiences a current of approximately 530 mA, exceeding the electromigration (EM) limit (e.g., approximately 300 mA) for each probe bump. Furthermore, the large current on each probe bump in these approaches can induce severe power bouncing, as power bouncing is proportional to the current rate-of-change (di/dt).

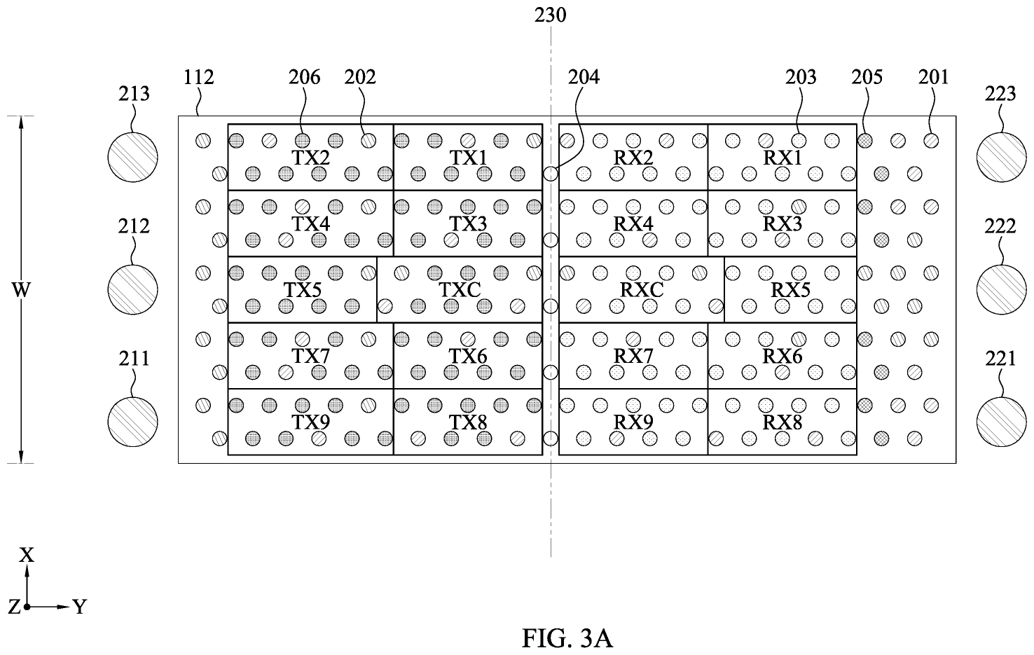

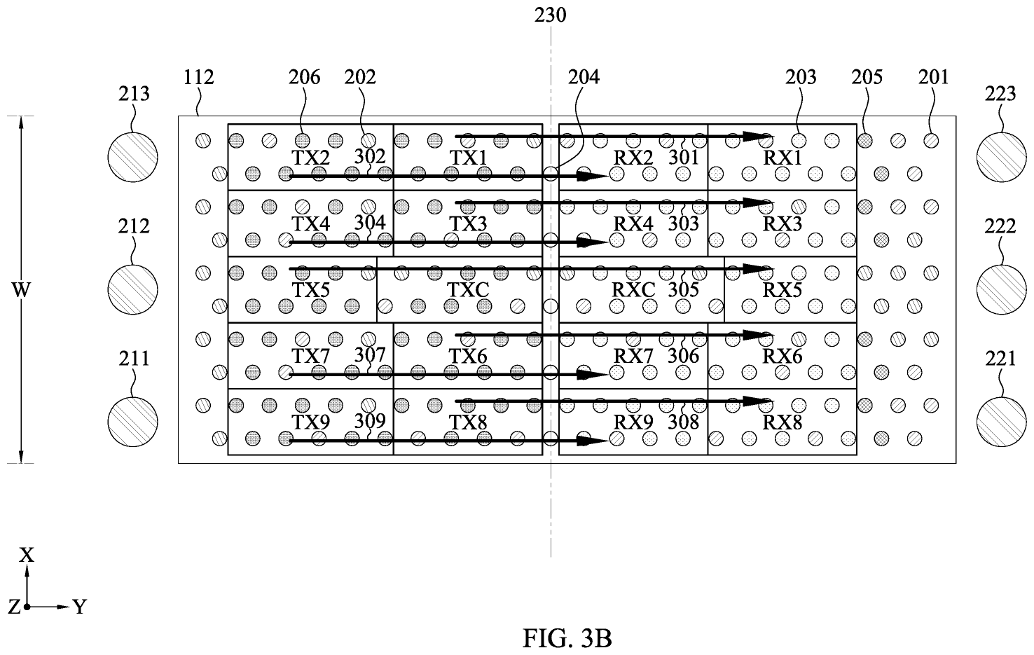

FIG. 3A is a plan view of an aPHY module in accordance with some embodiments of the present disclosure. FIG. 3B is a plan view of the aPHY module with segments in FIG. 3A.

In some embodiments, the microbumps 203, which represent receiver data (rxdata) microbumps, located on the right side of the aPHY module 112 can be divided into a plurality of segments RX1 to RX9. The microbumps 206, which represent transmitter data (txdata) microbumps, located on the left side of the aPHY module 112 can be divided into a plurality of segments TX1 to TX9, as depicted in FIG. 3A. Additionally, segments RX1 to RX9 correspond to segments TX1 to RX9, and the number of rxdata microbumps 203 in each segment RX1 to RX9 corresponds to that of txdata microbumps 206 in each segment TX1 to TX9. For example, segment TX1 includes 7 txdata microbumps 206, and its corresponding segment RX1 also includes 7 rxdata microbumps. Segment TX2 includes 8 txdata microbumps 206, and its corresponding segment RX2 also includes 8 rxdata microbumps, and so on. Additionally, segment TXC may include microbumps 206 for TX clock and I/O signals, while segment RXC may include microbumps 203 for RX clock and I/O signals.

In some embodiments, each segment TX1 to TX9 and its respective segment RX1 to RX9 may form 9 data-lane subsets (e.g., SUB1 to SUB9). The data transmission paths to transmit die-to-die test signals from the txdata microbumps 206 of the activated segments TX1 to TX9 to the corresponding rxdata microbumps 203 in their respective segments RX1 to RX9 are shown by arrows 301 to 309 in FIG. 3B, respectively. More specifically, during the KGD test of first die 110, one or more data-lane subsets (e.g., including a portion of segments TX1 to TX9 and their respective segment RX1 to RX9) can be activated sequentially, and the activated segments TX1 to TX9 may transmit die-to-die test signals from its txdata microbumps 206 to the corresponding rxdata microbumps 203 in the respective activated segments RX1 to RX9.

FIG. 4A is a diagram illustrating performing a KGD test on the first die using external test equipment in accordance with some embodiments of the present disclosure. FIG. 4B is a diagram illustrating the aPHY module during the KGD test in FIG. 4A.

In some embodiments, while performing the KGD test on the first die 110, external test equipment 40 may be electrically connected to first die 110. For example, the external test equipment 40 can be utilized to control the subset enable signal (e.g., SUB_EN) for each data-lane subset, allowing each data-lane subset to be activated sequentially. Additionally, the external test equipment 40 can provide the respective test pattern (e.g., specific die-to-die test signals) to the txdata microbumps 206 of the TX segment of the activated data-lane subset through the BIST circuit 113 or the control circuit 1111, as depicted in FIG. 4A, allowing the respective test pattern to be transmitted from the txdata microbumps 206 of the TX segment to the corresponding rxdata microbumps 203 of the RX segment of the activated data-lane subset.

In some embodiments, each of the data-lane subsets within the aPHY module 112 may be activated sequentially during the KGD test of the first die 110. As shown in FIG. 4B, the first data-lane subset, which includes segments TX1 and RX1, is activated. The die-to-die test signals can then be transmitted from the txdata microbumps 206 within segment TX1 to the corresponding rxdata microbumps 203 within segment RX1, as indicated by arrow 301 in FIG. 4A. Next, the second data-lane subset, which includes segments TX2 and RX2, is activated. The die-to-die test signals can then be transmitted from the txdata microbumps 206 within segment TX2 to the corresponding rxdata microbumps 203 within segment RX2.

More specifically, the overall power consumption of aPHY module 112 during the KGD test may include two components: first power consumption from data lines and second power consumption from clock and I/O signals. The first power consumption from the data lines is the major factor. By activating each data-lane subset within the first die 110 sequentially, the probe bumps 211 to 213 and 221 to 223 experience a lower current. As a result, the overall power consumption of the aPHY module 112 during the KGD test using one data-lane subset at a time can be reduced to 1/9 of the first power consumption plus the second power consumption from clock and I/O signals when all data-lanes are activated. This can significantly reduce overall power consumption of the aPHY module 112 during the KGD test.

Additionally, the proposed segmentation test methodology of the aPHY module 112 during the KGD test ensures that each probe bump 211 to 213 and 221 to 223 experiences a lower current, approximately 1/9 (e.g., approximately 60 mA) of the current (e.g., approximately 530 mA) when using all 64 data lanes. Consequently, the power bouncing over the aPHY module 112 is reduced, and the power distribution network over the aPHY module 112 and electromigration limit (e.g., 300 mA per probe bump) for each probe bump 211 to 213 and 221 to 223 can be relaxed.

FIG. 4C is a flowchart of a method for performing the KGD test of the first die in accordance with the embodiment of FIG. 4A.

The flow for performing the KGD test of the first die 110 using the segmentation test methodology is described with reference to FIG. 4C. In operation 410, a respective test pattern for each data-lane subset of an aPHY module 112 is received. In some embodiments, during the KGD test, the external test equipment 40 can provide the power supply voltage and ground voltage to the corresponding probe bumps 211 to 213 and 221 to 223 disposed at two opposite sides of the aPHY module 112. Additionally, the external test equipment 40 can provide the respective test pattern (e.g., specific die-to-die test signals) to the txdata microbumps 206 of the TX segment within the activated data-lane subset through the control circuit 1111 (or the BIST circuit 113).

In operation 420, each data-lane subset is sequentially activated and tested using the respective test pattern to obtain respective subset test data. In some embodiments, the external test equipment 40 may sequentially assert the subset enable signal (e.g., SUB1_EN to SUB9_EN) for each data-lane subset per predetermined period of time.

In operation 430, the subset test data is analyzed to identify the subset test result. In some embodiments, the external test equipment 40 may organize the data received from the rxdata microbumps 203 of the RX segment within the activated data-lane subset as the respective subset test data, and determine whether the respective subset test data complies with the respective test pattern. In response to the respective subset test data complying with the respective test pattern, the external test equipment 40 can determine that the currently activated data-lane subset works normally, which may be represented by a value of 0 (e.g., an operating status). In response to the respective subset test data not complying with the respective test pattern, the external test equipment 40 can determine that the currently activated data-lane subset does not work normally, which may be represented by a value of 1 (e.g., a non-operating status).

In operation 440, the respective subset test result of each data-lane subset is merged to obtain an overall test result of the aPHY module 112. In some embodiments, the overall test result may be an N-bit value (e.g., N=9, depending on the number of data-lane subsets), and the external test equipment 40 can determine whether all bits in the overall test result is 0. In response to all bits in the overall test result being 0, the external test equipment 40 can determine that the aPHY module 112 works normally, and the KGD test of the first die 110 passes. In response to any bit in the overall test result being 1, the external test equipment 40 can determine that the aPHY module 112 does not work normally, and the KGD test of the first die 110 fails. Furthermore, the subset test results can be used by the designer of the first die 110 to quickly identify failures in one or more data-lane subsets within the aPHY module 112, thereby expediting the system debugging process of the first die 110 and the semiconductor packages 100A to 100C shown in FIGS. 1A to IC.

FIG. 4D is a simplified diagram of the aPHY module with the control circuit in accordance with some embodiments of the present disclosure. FIG. 4E is a schematic diagram of the control circuit in FIG. 4D. FIG. 4F is a schematic diagram of a clock gating component in FIG. 4D.

In some embodiments, referring to FIG. 4D, the segments TX1 and RX1 can be collectively referred to as a data-lane subset SUB1, while the segments TX2 and RX2 can be collectively referred to as a data-lane subset SUB2, and so on. Accordingly, there are nine data-lane subsets SUB1 to SUB9 within the aPHY module 112, which can be classified into 5 rows. For brevity, microbumps 201 to 206 are not shown in FIG. 4D. For example, the first row may include data-lane subsets SUB1 and SUB2, where the data-lane subset SUB1 includes segments TX1 and RX1, while the data-lane subset SUB2 includes segments TX2 and RX2.

In some embodiments, the RX segments (e.g., RX1 to RX9) on each row receive a clock signal CK through respective AND gates 422R to 430R, while the TX segments (e.g., TX1 to TX9) on each row may receive the clock signal CK through respective AND gates 422T to 430T, as shown in FIG. 4D. The clock signal CK may be transmitted to the respective clock gating component 432 of each TX and RX segment.

FIG. 4E shows the schematic diagram of the segments RX1 and RX2 in the first row for descriptive purposes. Each of the other segments RX3 to RX9 and TX1 to TX9 has a similar arrangement. Additionally, the segment RX2 may include 8 data lanes DL2, while the segment RX1 may include 7 data lanes DL1 plus a dummy data lane DMY. The clock signal CK may be transmitted to the respective clock gating components 432 within the segments RX1 and RX2 though one or more clock buffers 431 disposed on the respective clock path. The clock gating component 432 within the segment RX1 may perform clock gating between the clock signal CK and the respective subset enable signal SUB1_EN, while the clock gating component 432 within the segment RX2 may perform clock gating between the clock signal CK and the respective subset enable signal SUB2_EN. The clock gating component 432, as shown in FIG. 4F, can be implemented using an AND gate, but other implementations are also possible.

In some embodiments, when the data-lane subset SUB1 is activated, the remaining data-lane subsets SUB2 to SUB9 are deactivated. At this time, the subset enable signals SUB1_EN from the external test equipment 40 is in the high logic state (e.g., “1”), allowing the clock signal CK to pass through the clock gating component 432 and reach the correction circuits 433 within the segment RX1, enabling the operation of the data lanes DL1 within the segment RX1. On the other hand, the subset enable signals SUB2_EN from the external test equipment are in the low logic state (e.g., “0”), causing the clock signal CK to be blocked by the respective clock gating component 432. As a result, the clock signal does not reach the correction circuits 433 within the segment RX2, and the data lanes DL2 do not receive the clock signals, rendering them non-operational. The correction circuits 433 within the segments RX1 and RX2 are configured to perform duty-cycle correction (DCC) and quadrature-error correction (QEC) on the received clock signal CK on respective clock paths to the data lanes DL1 and DL2.

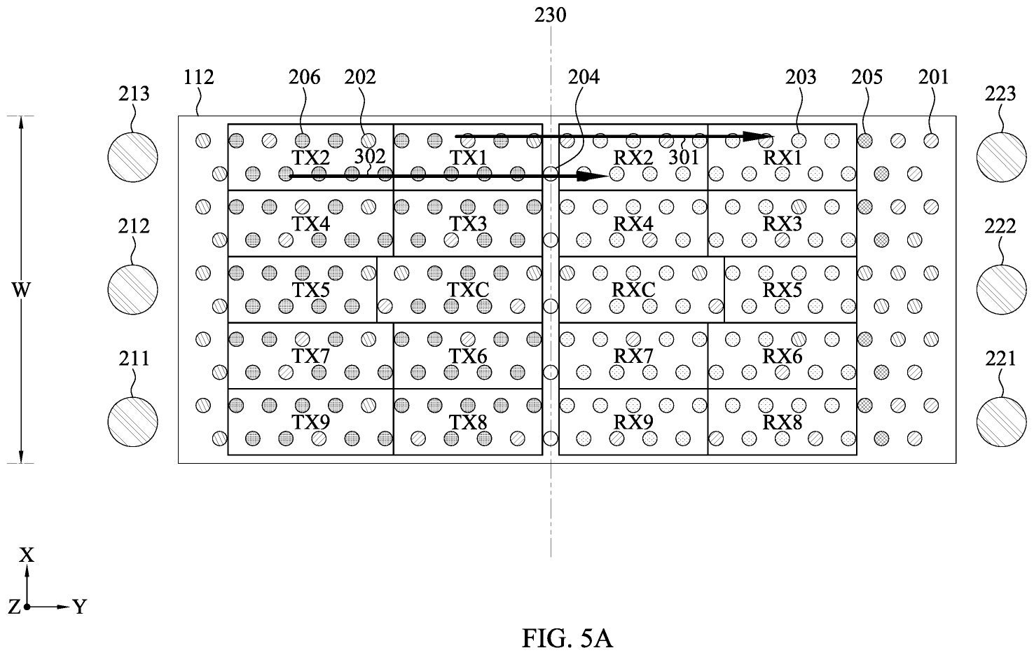

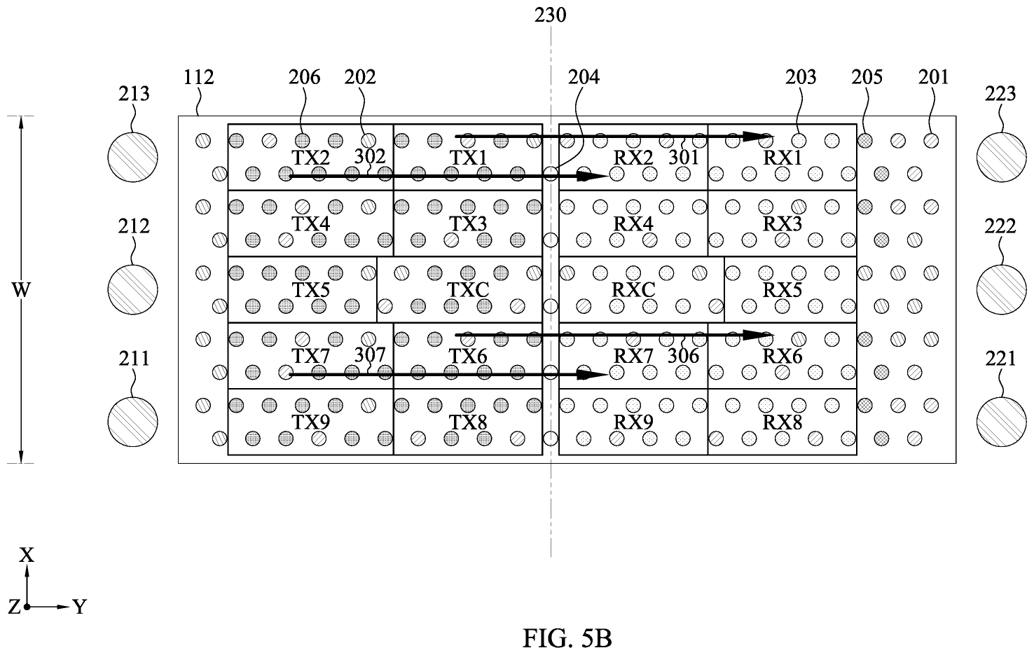

FIG. 5A is another diagram illustrating the aPHY module during the KGD test in FIG. 4A.

In some embodiments, the external test equipment 40 can perform the KGD test on the data-lane subsets within the aPHY module 112 row by row. For example, during the KGD test of the first die 110, the external test equipment 40 can enable one or more data-lane subsets, which are on the same row, of the aPHY module 112 at one time. For example, the external test equipment 40 can first activate and test the data-lane subsets SUB1 and SUB2 within the first row at the same time, with the subset enable signals SUB1_EN and SUB2_EN being in the high logic state (e.g., “1”). Subsequently, the external test equipment 40 can activate and test the data-lane subsets SUB3 and SUB4 within the second row at the same time. Next, the external test equipment 40 can activate and test the data-lane subset SUB5 within the third row. Then, the external test equipment 40 can activate and test the data-lane subsets SUB6 and SUB7 within the fourth row at the same time. At last, the external test equipment 40 can activate and test the data-lane subsets SUB8 and SUB9 within the fifth row at the same time. Upon the test of the data-lane subsets SUB8 and SUB9 being complete, the KGD test of first die 110 ends.

In some embodiments, the external test equipment 40 can perform the KGD test on two of the data-lane subsets within the aPHY module 112 at one time. For example, the external test equipment 40 can first activate and test the data-lane subsets SUB1 and SUB2 within the first row at the same time, with the subset enable signals SUB1_EN and SUB2_EN being in the high logic state (e.g., “1”). Subsequently, the external test equipment 40 can activate and test the data-lane subsets SUB3 and SUB4 within the second row at the same time. Next, the external test equipment 40 can activate and test the data-lane subsets SUB5 and SUB6 respectively within the third row and the fourth row at the same. Then, the external test equipment 40 can activate and test the data-lane subsets SUB7 and SUB8 respectively within the fourth row and fifth row at the same time. At last, the external test equipment 40 can activate and test the data-lane subset SUB9 within the fifth row. Upon the test of the data-lane subsets SUB8 and SUB9 being complete, the KGD test of first die 110 ends.

In some embodiments, the external test equipment 40 can collect the respective subset test result in a manner similar to that described in the embodiment of FIG. 4C, and then merge the respective subset test result of each data-lane subset to obtain the overall test result of the aPHY module 112.

It should be noted that the segmentation test methodology described in the embodiment of FIG. 5A can accelerate the KGD test, as the current experienced by each probe bump 211 to 213 and 221 to 223 does not exceed the electromigration limit (e.g., 300 mA). For example, the current experienced by each probe bump is approximately 2/9 (e.g., 120 mA) of the current (e.g., approximately 530 mA) when using all 64 data lanes within the aPHY module 112.

FIG. 5B is yet another diagram illustrating the aPHY module during the KGD test in FIG. 4A.

In some embodiments, the external test equipment 40 can perform the KGD test on the data-lane subsets, which are on multiple rows, within the aPHY module 112 at one time. For example, during the KGD test of the first die 110, the external test equipment 40 can enable the data-lane subsets, which are on two different rows, of the aPHY module 112 at one time. For example, the external test equipment 40 can first activate and test the data-lane subsets SUB1 and SUB2 within the first row and the data-lane subsets SUB6 and SUB7 within the fourth row at the same time. Subsequently, the external test equipment 40 can activate and test the data-lane subsets SUB3 and SUB4 within the second row and the data-lane subsets SUB8 and SUB9 within the fifth row at the same time. At last, the external test equipment 40 can activate and test the data-lane subset SUB5 within the third row. Upon the test of the data-lane subset SUB5 being complete, the KGD test of first die 110 ends. Here, the two activated rows are not adjacent, resulting in a more balanced voltage and current distribution over the aPHY module 112.

In some embodiments, the external test equipment 40 can perform the KGD test on four of the data-lane subsets within the aPHY module 112 at one time, where the activation scheme of the data-lane subsets may be similar to that described above. In some embodiments, the numbers of the four activated data-lane subsets may be consecutively, and the four activated data-lane subsets can be on the adjacent rows.

In some embodiments, the external test equipment 40 can collect the respective subset test result in a manner similar to that described in the embodiment of FIG. 4C, and then merge the respective subset test result of each data-lane subset to obtain the overall test result of the aPHY module 112.

In some embodiments, the number of activated subsets is less than half of all the subsets, preventing the current experienced by each probe bump from exceeding the electromigration limit.

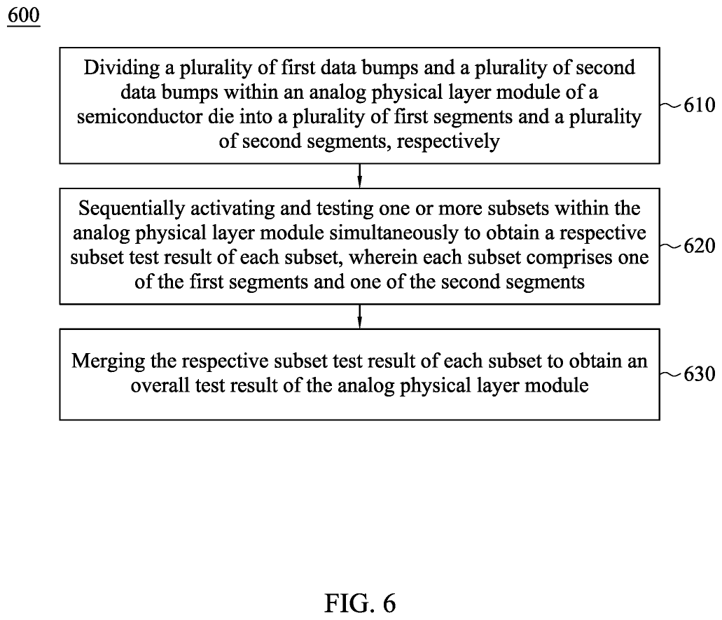

FIG. 6 is a flowchart of a method for testing an analog physical layer module within a semiconductor die in accordance with some embodiments of the present disclosure.

In operation 610, a plurality of first data bumps and a plurality of second data bumps within an analog physical layer module of a semiconductor die are divided into a plurality of first segments and a plurality of second segments, respectively. For example, the first data bumps and the second data bumps may be txdata microbumps 206 and rxdata microbumps 203 shown in FIG. 3A. Additionally, the first segments and the second segments may be segments TX1 to TX9 and RX1 to RX9 shown in FIG. 3A.

In operation 620, sequentially activating and testing one or more subsets within the analog physical layer module to obtain a respective subset test result of each subset, wherein each subset comprises one of the first segments and one of the second segments. For example, as described in the embodiments of FIGS. 4B, 5A and 5B, different numbers of subsets can be activated and tested simultaneously. Additionally, the number of activated subsets is less than half of all the subsets, preventing the current experienced by each probe bump from exceeding the electromigration limit.

In operation 630, merging the respective subset test result of each subset to obtain an overall test result of the analog physical layer module. In some embodiments, the overall test result may be an N-bit value (e.g., N=9, depending on the number of data-lane subsets), and the external test equipment 40 can determine whether all bits in the overall test result is 0. In response to all bits in the overall test result being 0, the external test equipment 40 can determine that the aPHY module 112 works normally, and the KGD test of the first die 110 passes. In response to any bit in the overall test result being 1, the external test equipment 40 can determine that the aPHY module 112 does not work normally, and the KGD test of the first die 110 fails.

An aspect of the present disclosure provides a method, which includes the following steps: dividing a plurality of first data bumps and a plurality of second data bumps within an analog physical layer module of a semiconductor die into a plurality of first segments and a plurality of second segments, respectively; sequentially activating and testing one or more subsets within the analog physical layer module simultaneously to obtain a respective subset test result of each subset, wherein each subset comprises one of the first segments and one of the second segments; and merging the respective subset test result of each subset to obtain an overall test result of the analog physical layer module.

Another aspect of the present disclosure provides a semiconductor die, which includes an analog physical layer module and a control circuit. The analog physical layer module includes a plurality of first data bumps and a plurality of second data bumps. The control circuit is configured to control the analog physical layer module during a test of the semiconductor die. The plurality of first data bumps and the plurality of second data bumps are divided into a plurality of first segments and a plurality of second segments, respectively. The first segments and the second segments are grouped into a plurality of subsets, and each subset comprises one of the first segments and one of the second segments. The test is performed on each subset sequentially to obtain a respective subset test result of each subset that is merged to obtain an overall test result of the semiconductor die.

Yet another aspect of the present disclosure provides a method, which includes the following steps: receiving a respective test pattern for each data-lane subset within an analog physical layer module; activating and testing each data-lane subset sequentially using the respective test pattern for each data-lane subset to obtain respective subset test data of each data-lane subset; analyzing the subset data to identify a respective subset test result of each data-lane subset; and merging the respective subset test result of each data-lane subset to obtain a test result of the analog physical layer module.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A method, comprising:
dividing a plurality of first data bumps and a plurality of second data bumps within an analog physical layer module of a semiconductor die into a plurality of first segments and a plurality of second segments, respectively;
sequentially activating and testing one or more subsets within the analog physical layer module simultaneously to obtain a respective subset test result of each subset, wherein each subset comprises one of the first segments and one of the second segments; and
merging the respective subset test result of each subset to obtain an overall test result of the analog physical layer module.

2. The method of claim 1, wherein the first data bumps and the second data bumps are transmitter data bumps and receiver data bumps, respectively.

3. The method of claim 2, wherein a first number of the first data bumps in the first segment is equal to a second number of the second data bumps in the second segment within each subset.

4. The method of claim 3, wherein sequentially activating and testing the one or more subsets within the analog physical layer module simultaneously to obtain the respective subset test result of each subset comprises:
sequentially receiving one or more subset enable signals corresponding to the one or more subsets to be activated from external test equipment; and
activating the one or more subsets simultaneously using the one or more subset enable signals.

5. The method of claim 4, wherein sequentially activating and testing the one or more subsets within the analog physical layer module simultaneously to obtain the respective subset test result of each subset further comprises:
receiving a respective test pattern of each subset within the analog physical layer module from external test equipment;
transmitting, by the external test equipment, the respective test pattern through the first data bumps of the first segment within each subset; and
receiving, by the external test equipment, the respective test pattern through the second data bumps of the second segment within each subset to obtain respective subset test data of each subset.

6. The method of claim 5, wherein sequentially activating and testing the one or more subsets within the analog physical layer module simultaneously to obtain the respective subset test result of each subset further comprises:
determining, by the external test equipment, whether the respective subset test data of each subset complies with the respective test pattern of each subset;
in response to the respective subset test data of each subset complying with the respective test pattern of each subset, determining the respective subset test result each subset as an operating status; and
in response to the respective subset test data of each subset not complying with the respective test pattern of each subset, determining the respective subset test result each subset as a non-operating status.

7. The method of claim 6, wherein the testing is a known-good-die test of the semiconductor die.

8. The method of claim 1, wherein less than half of the subsets are activated simultaneously.

9. The method of claim 1, further comprising:
providing a clock signal to the first data bumps of the first segment and the second data bumps of the second segment within each activated subset; and
deactivating the clock signal provided to the first data bumps of the first segment and the second data bumps of the second segment within each of deactivated subsets.

10. A semiconductor die, comprising:
an analog physical layer module, comprising a plurality of first data bumps and a plurality of second data bumps; and
a control circuit, configured to control the analog physical layer module during a test of the semiconductor die,
wherein the plurality of first data bumps and the plurality of second data bumps are divided into a plurality of first segments and a plurality of second segments, respectively,
wherein the first segments and the second segments are grouped into a plurality of subsets, and each subset comprises one of the first segments and one of the second segments,
wherein the test is performed on each subset sequentially to obtain a respective subset test result of each subset that is merged to obtain an overall test result of the semiconductor die.

11. The semiconductor die of claim 10, wherein the test is a known-good-die test.

12. The semiconductor die of claim 10, wherein the plurality of subsets are arranged into a plurality of rows, and each row comprises two of the subsets.

13. The semiconductor die of claim 12, wherein when a first subset on a specific row is activated by the control circuit, the control circuit is configured to provide a clock signal to the first subset on the specific row and deactivate the clock signal provided to a second subset on the specific row.

14. The semiconductor die of claim 13, wherein the control circuit comprises a clock gating component for each subset that performs clock gating between the clock signal and a respective subset enable signal of each subset.

15. The semiconductor die of claim 14, wherein the control circuit further comprises a correction circuit disposed on a respective clock path to the first segment and the second segment within each subset, and configured to perform duty-cycle correction and quadrature-error correction on the clock signal.

16. The semiconductor die of claim 14, wherein the control circuit further comprises one or more clock buffers disposed on a respective clock path to the first segment and the second segment within each subset.

17. The semiconductor die of claim 14, wherein a plurality of probe bumps are disposed at two opposite side of the analog physical layer module, and external test equipment provides a power supply voltage and a ground voltage to the analog physical layer module through the probe bumps, wherein the probe bumps are relatively larger than the first data bumps and the second data bumps.

18. A method, comprising:
receiving a respective test pattern for each data-lane subset within an analog physical layer module;
activating and testing each data-lane subset sequentially using the respective test pattern for each data-lane subset to obtain respective subset test data of each data-lane subset;
analyzing the subset data to identify a respective subset test result of each data-lane subset; and
merging the respective subset test result of each data-lane subset to obtain a test result of the analog physical layer module.

19. The method of claim 18, wherein the analog physical layer module is fabricated on a semiconductor die.

20. The method of claim 18, wherein each data-lane subset comprises:
a transmitter segment, comprising a plurality of transmitter microbumps; and
a receiver segment, comprising a plurality of receiver microbumps that correspond to the transmitter microbumps.
